(19) United States
(12) Patent Application Publication
(10) Pub. No.: US 2025/0338526 A1
(43) Pub. Date: Oct. 30, 2025

(54) SEMICONDUCTOR DEVICE AND METHOD OF FABRICATING THE SAME

(71) Applicant: National Tsing Hua University, Hsinchu City (TW)

(72) Inventors: King Yuen Wong, Hsinchu City (TW); Haoran Wang, Hsinchu City (TW)

(73) Assignee: National Tsing Hua University, Hsinchu City (TW)

(21) Appl. No.: 18/752,814

(22) Filed: Jun. 25, 2024

(30) Foreign Application Priority Data
Apr. 29, 2024 (TW) 113116013

(51) Int. Cl. H01L 29/739; H01L 29/06; H01L 29/66

(52) U.S. Cl. CPC H10D 12/481; H10D 12/038; H10D 62/111; H10D 62/124

(57) ABSTRACT

A semiconductor device includes a substrate and units. Each unit includes a drift layer, a fin, a first, second, and third doped region, and a first gate structure. The drift layer is located on a first surface of the substrate. The fin is located on a first surface of the drift layer. The first doped region is located in the fin and extends from a top surface of the fin toward the drift layer. The second doped region is located in the substrate and extends from a second surface of the substrate toward the first surface of the substrate. The third doped region is located in the drift layer and extends from the first surface of the drift layer toward a second surface of the drift layer. The first gate structure is between the first and third doped regions and extends to the first surface of the drift layer.

### CROSS-REFERENCE TO RELATED APPLICATION

This application claims the priority benefit of Taiwan application serial no. 113116013, filed on Apr. 29, 2024. The entirety of the above-mentioned patent application is hereby incorporated by reference herein and made a part of this specification.

### BACKGROUND

### Technical Field

The disclosure relates to an integrated circuit and a method of fabricating the same, and in particular to a semiconductor device and a method of fabricating the same.

### Description of Related Art

The ultra-wide bandgap power device (for example, Ga₂O₃) has high critical field and is a potential candidate for a power rectifier and a switch due to the low on-resistance and the high blocking voltage thereof. Some literature has demonstrated the superior performance of the Ga₂O₃ power device. However, uneven electric field distribution leads to a local peak field, thereby reducing the breakdown voltage and the reliability of the device.

### SUMMARY

The disclosure provides a semiconductor device with low on-resistance, high cut-off voltage, and high breakdown voltage and a method of fabricating the same.

A semiconductor device of the disclosure includes a substrate and multiple units. Each unit includes a drift layer, a fin, a first doped region, a second doped region, a first doped pillar, and a first gate structure. The drift layer is located on a first surface of the substrate. The fin is located on a first surface of the drift layer. The first doped region is located in the fin and extends from a top surface of the fin toward the drift layer. The second doped region is located in the substrate and extends from a second surface of the substrate toward the first surface of the substrate. The first doped pillar is located in the drift layer and extends from the first surface of the drift layer toward a second surface of the drift layer. The first gate structure is between the first doped region and the first doped pillar, is on a first side wall of the fin, and extends to the first surface of the drift layer.

A method of fabricating a semiconductor device of the disclosure includes the following steps. A substrate is provided. Multiple units are formed. Forming each unit includes the following steps. A drift layer is formed on a first surface of the substrate. A first doped region is formed in the drift layer. A part of the drift layer with the first doped region is pattered to form a fin. A second doped region is formed on a second surface of the substrate. A first doped pillar extending from the first surface of the drift layer toward a second surface of the drift layer is formed in the drift layer. A first gate structure extending to the first surface of the drift layer is formed between the first doped region and the first doped pillar and on a first side wall of the fin.

In the embodiments of the disclosure, a super junction configuration and an insulated gate bipolar transistor (IGBT) device structure are applied to a Ga₂O₃ power device, which can break through the current limit of the traditional Ga₂O₃ power device and implement low on-resistance, high cut-off voltage, and high breakdown voltage.

### BRIEF DESCRIPTION OF THE DRAWINGS

FIG. 1A to FIG. 1F are schematic cross-sectional views of a method of fabricating a semiconductor device according to an embodiment of the disclosure.

FIG. 2A to FIG. 2F are schematic cross-sectional views of a method of fabricating a semiconductor device according to another embodiment of the disclosure.

FIG. 3A to FIG. 3D are schematic cross-sectional views of a method of fabricating a gate structure of a semiconductor device at an intermediate stage according to an embodiment of the disclosure.

### DESCRIPTION OF THE EMBODIMENTS

In the disclosure, a super junction configuration and an insulated gate bipolar transistor (IGBT) device structure are applied to a Ga₂O₃ power device, which can break through the current limit of the traditional Ga₂O₃ power device, improve reverse blocking voltage without reducing conduction performance, and implement low on-resistance and high breakdown voltage.

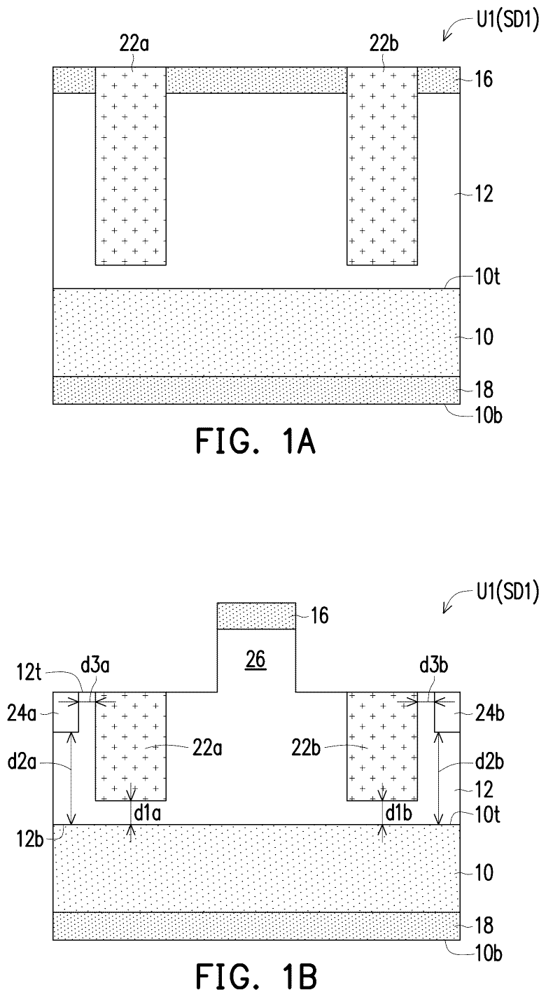

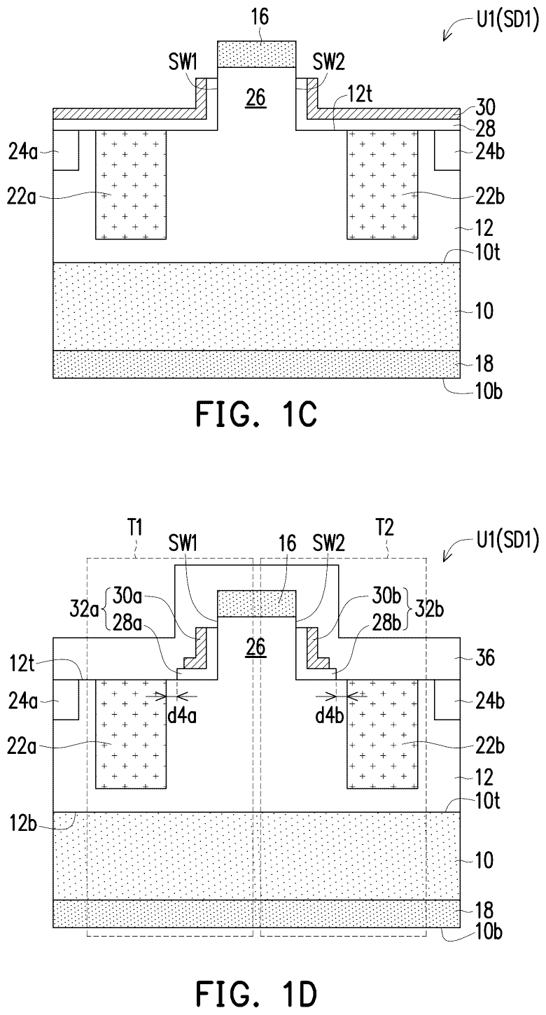

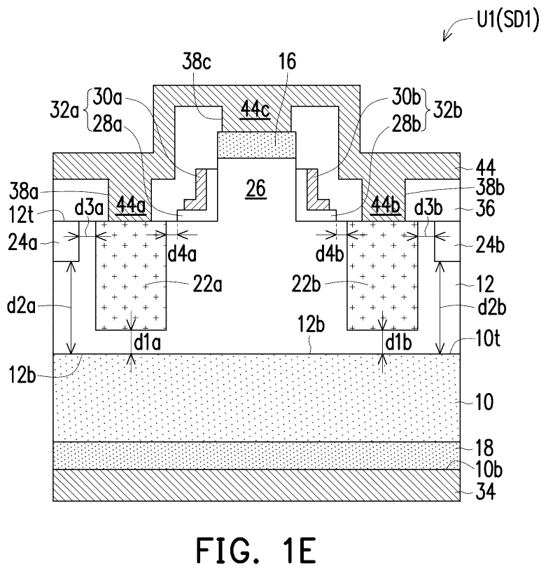

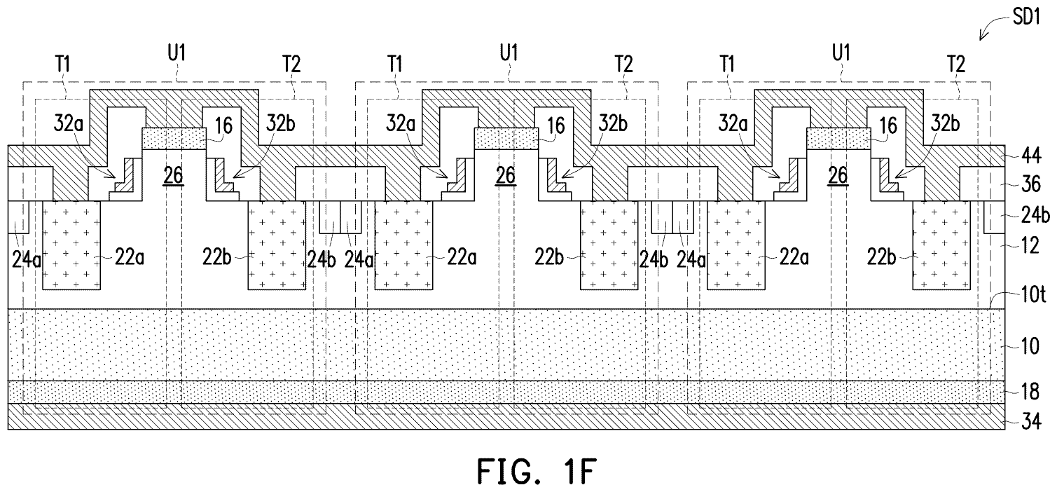

FIG. 1A to FIG. 1F are schematic cross-sectional views of a method of fabricating a semiconductor device according to an embodiment of the disclosure. A semiconductor device SD1 of the embodiment includes multiple units U1. For the sake of simplicity, a single unit U1 is illustrated in FIG. 1A to FIG. 1E. Multiple units U1 are illustrated in FIG. 1F. The semiconductor device SD1 of the embodiment includes a metal-oxide semi-field effect transistor with a super junction configuration.

Referring to FIG. 1A, the method of fabricating the semiconductor device SD1 includes forming a drift layer 12 on a first surface 10t of a substrate 10. The substrate 10 may have a first conductivity type, such as n type. The substrate 10 is, for example, a semiconductor compound with a first conductivity type. The substrate 10 is, for example, an n-type heavily doped Ga₂O₃ (n+Ga₂O₃) substrate or an n-type heavily doped GaN (n+GaN) substrate. The thickness of the substrate 10 is, for example, 250 μm to 650 μm.

The drift layer 12 may have a first conductivity type, such as n type. The drift layer 12 may be a semiconductor compound with a first conductivity type, such as an n-type lightly doped Ga₂O₃ or an n-type lightly doped GaN. The doping concentration of the drift layer 12 may be less than the doping concentration of the substrate 10. The drift layer 12 may be formed by epitaxial growth. The thickness of the drift layer 12 is, for example, 5 μm to 10 μm.

Referring to FIG. 1A, next, a first doped region 16 is formed in the drift layer 12, and a second doped region 18 is formed in the substrate 10. The first doped region 16 and the second doped region 18 have a first conductivity type, such as n type. The first doped region 16 and the second doped region 18 may be respectively used as a source region and a drain region. The first doped region 16 and the second doped region 18 may be semiconductor compounds with a first conductivity type, such as an n-type heavily doped Ga₂O₃ (n++Ga₂O₃) or an n-type heavily doped GaN (n++GaN). The first doped region 16 and the second doped region 18 include Si or Sn dopants. The doping concentrations of the first doped region 16 and the second doped region 18 are greater than the doping concentrations of the drift layer 12 and the substrate 10. The first doped region 16 and the second doped region 18 may be respectively formed by ion implantation. The depths of the first doped region 16 and the second doped region 18 are, for example, 0.1 μm to 0.5 μm.

Afterwards, referring to FIG. 1A, a first doped pillar 22a and a second doped pillar 22b are formed in the drift layer 12. The first doped pillar 22a and the second doped pillar 22b have a second conductivity type, such as p type. The first doped pillar 22a and the second doped pillar 22b may be semiconductor compounds with a second conductivity type, such as NiO, Cu₂O, In₂O₃, ZnO, IGZO, other oxide semiconductors, or p-type doped GaN. In some embodiments, a method of forming the first doped pillar 22a and the second doped pillar 22b is as follows. Multiple grooves are formed in the drift layer 12 by a photolithography and etching process. A deposition process is then performed to deposit a semiconductor compound material with a second conductivity type, and excess material is removed by an etch-back process or a planarization process.

Referring to FIG. 1B, the photolithography and etching process is performed to pattern a part of the drift layer 12 with the first doped region 16, thereby forming a fin 26 between the remaining first doped pillar 22a and second doped pillar 22b. The fin 26 protrudes from a first surface 12t of the remaining drift layer 12. Therefore, the fin 26 may also be referred to as a protrusion. Then, a first isolation structure 24a and a second isolation structure 24b are formed in the drift layer 12. The first isolation structure 24a and the second isolation structure 24b are located on two sides of the fin 26. The first isolation structure 24a is adjacent to the first doped pillar 22a and is spaced therefrom by a non-zero distance d3a in the lateral direction. The second isolation structure 24b is adjacent to the second doped pillar 22b and is spaced therefrom by a non-zero distance d3b in the lateral direction. The first isolation structure 24a and the second isolation structure 24b may be formed by forming an ion implantation mask and performing an ion implantation process. Ions implanted in the ion implantation process include N, Ar, F, or a combination thereof.

The first isolation structure 24a, the second isolation structure 24b, the first doped pillar 22a, and the second doped pillar 22b all extend from the first surface 12t of the drift layer 12 toward a second surface 12b. The depths of the first doped pillar 22a and the second doped pillar 22b are, for example, 0.1 μm to 11 μm. The first doped pillar 22a is spaced from the first surface 12t of the drift layer 12 by a non-zero distance d1a in the longitudinal direction. The second doped pillar 22b is spaced from the first surface 12t of the drift layer 12 by a non-zero distance d1b in the longitudinal direction. The first isolation structure 24a is spaced from the first surface 12t of the drift layer 12 by a non-zero distance d2a in the longitudinal direction. The second isolation structure 24b is spaced from the first surface 12t of the drift layer 12 by a non-zero distance d2b in the longitudinal direction. In the embodiment, the first doped pillar 22a and the second doped pillar 22b are closer to the first surface 12t of the drift layer 12 than the first isolation structure 24a and the second isolation structure 24b. That is, d1a<d2a and d1b<d2b. The distances d1a and d1b are, for example, 0.1 μm to 5 μm.

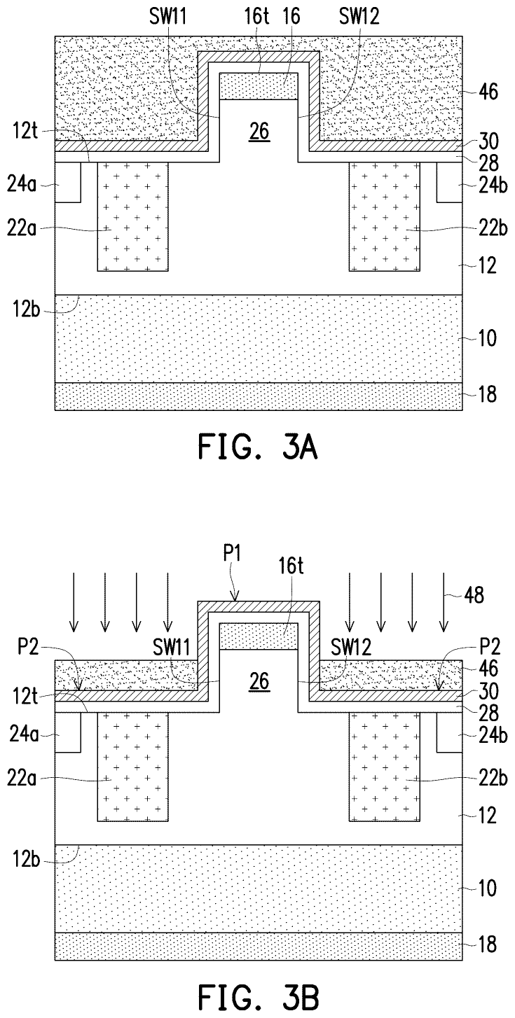

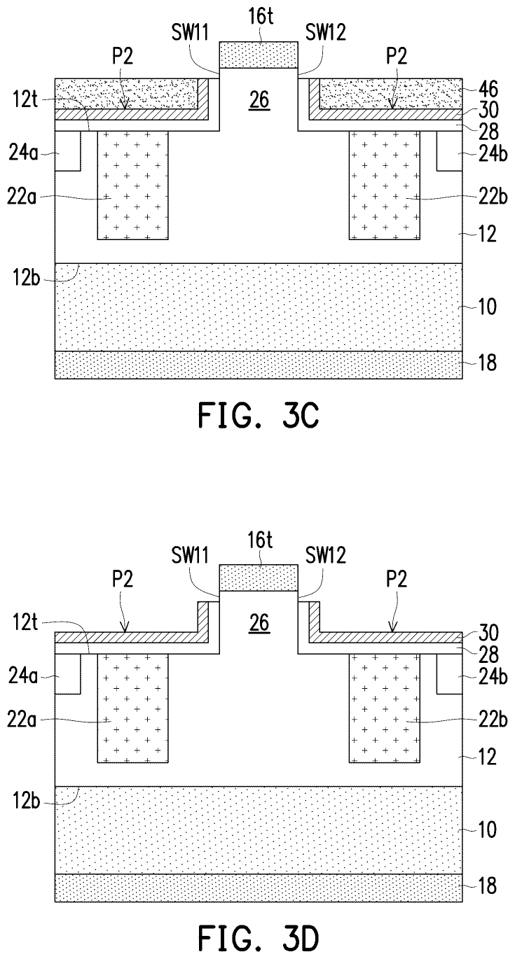

Referring to FIG. 1C, a gate dielectric layer 28 and a gate conductor layer 30 are formed. A method of forming the gate dielectric layer 28 and the gate conductor layer 30 may be described below with reference to FIG. 3A to FIG. 3D. FIG. 3A to FIG. 3D are schematic cross-sectional views of a method of fabricating a gate structure of a semiconductor device at an intermediate stage according to an embodiment of the disclosure.

Referring to FIG. 3A, the gate dielectric layer 28 and the gate conductor layer 30 are formed on the first surface 12t of the drift layer 12 and a first side wall SW1, a top surface 16t, and a second side wall SW2 of the fin 26. The gate dielectric layer 28 is, for example, silicon oxide, aluminum oxide, or other dielectric materials. The gate conductor layer 30 may be metal, metal nitride, or a combination thereof, such as TiN, Ni, Au, Pt, or a combination thereof. The thickness of the gate dielectric layer 28 is, for example, 1 μm to 150 μm. The thickness of the gate conductor layer 30 is, for example, 5 μm to 500 μm. Next, a mask layer 46 is formed to cover the gate conductor layer 30. The mask layer 46 may be an organic material, such as a photoresist.

Referring to FIG. 3B, a plasma treatment 48 is performed to remove a part of the mask layer 46, so that a first portion P1 of the gate conductor layer 30 is exposed. Gas used in the plasma treatment 48 includes oxygen. The first portion P1 of the gate conductor layer 30 covers a top surface 26t and upper parts of the first side wall SW1 and the second side wall SW2 of the fin 26. The remaining mask layer 46 covers a second portion P2 of the gate conductor layer 30. The second portion P2 of the gate conductor layer 30 covers lower parts of the first side wall SW1 and the second side wall SW2 of the fin 26 and the first surface 12t of the drift layer 12.

Referring to FIG. 3C, an etching process is performed to remove the first portion P1 of the gate conductor layer 30 and the gate dielectric layer 28 below, so that the first doped region 16 and the upper parts of the first side wall SW1 and the second side wall SW2 of the fin 26 are exposed. During the etching process, the mask layer 46 may protect the second portion P2 of the gate conductor layer 30 and the gate dielectric layer 28 below from being damaged by etching.

Referring to FIG. 3D, the mask layer 46 is removed. The remaining gate conductor layer 30 and gate dielectric layer 28 are located on the first surface 12t of the drift layer 12 and the lower parts of the first side wall SW1 and the second side wall SW2 of the fin 26, as shown in FIG. 3D and FIG. 1C.

Referring to FIG. 1D, an etching process, a patterning process, or any other feasible process is performed to remove a part of the gate conductor layer 30 and the gate dielectric layer 28 to form gate conductor layers 30a and 30b and gate dielectric layers 28a and 28b. The gate conductor layer 30a and the gate dielectric layer 28a form a first gate structure 32a. The gate conductor layer 30b and the gate dielectric layer 28b form a second gate structure 32b. The first gate structure 32a exposes the upper part of the first side wall SW1 of the fin 26, and the second gate structure 32b exposes the upper part of the second side wall SW2 of the fin 26.

The first gate structure 32a is located between the first doped region 16 and the first doped pillar 22a, is on the lower part of the first side wall SW1 of the fin 26, and extends to the first surface 12t of the drift layer 12. The second gate structure 32b is located between the first doped region 16 and the second doped pillar 22b, is on the lower part of the second side wall SW2 of the fin 26, and extends to the first surface 12t of the drift layer 12. The gate dielectric layer 28a of the first gate structure 32a may be spaced from the first doped pillar 22a by a non-zero distance d4a. The gate dielectric layer 28a of the first gate structure 32a may be spaced from the first doped pillar 22a by a zero distance (not shown). The gate dielectric layer 28a of the first gate structure 32a may partially cover a top surface (not shown) of the first doped pillar 22a. Likewise, the gate dielectric layer 28b of the second gate structure 32b may be spaced from the second doped pillar 22b by a zero distance (not shown). The gate dielectric layer 28b of the second gate structure 32b may partially cover a top surface (not shown) of the second doped pillar 22b.

The fin 26, the drift layer 12, the substrate 10, the first gate structure 32a, the second gate structure 32a, the first doped region 16, the second doped region 18, the first doped pillar 22a, and the second doped pillar 22b of the embodiment of the disclosure form the unit U1. The fin 26, the drift layer 12, the substrate 10, the first gate structure 32a, the first doped region 16, the second doped region 18, and the first doped pillar 22a form a first transistor T1. The fin 26, the drift layer 12, the substrate 10, the second gate structure 32a, the first doped region 16, the second doped region 18, and the second doped pillar 22b form a second transistor T2. In other words, the unit U1 includes the first transistor T1 and the second transistor T2.

Continuing to refer to FIG. 1D, a passivation layer 36 is formed on the drift layer 12 and the fin 26. The material of the passivation layer 36 may be a dielectric material, such as silicon oxide, silicon nitride, or a combination thereof. The passivation layer 36 may be a conformal layer that substantially conformally covers the drift layer 12, the fin 36, the first gate structure 32a, and the second gate structure 32a (as shown in FIG. 1D). The passivation layer 36 may also be a flat layer (not shown) with a thicker thickness and a flat surface via a chemical mechanical planarization process.

Referring to FIG. 1E, a photolithography and etching process is then performed to form contact holes 38a, 38b, and 38c in the passivation layer 36 to respectively expose the first doped pillar 22a, the second doped pillar 22b, and the first doped region 16. After that, a first conductor layer 44, a second conductor layer 34, and contact windows 44a, 44b, and 44c are formed. The contact window 44a electrically connects the first doped pillar 22a and the first conductor layer 44. The contact window 44b electrically connects the second doped pillar 22b and the first conductor layer 44. The contact window 44c electrically connects the first doped region 16 and the first conductor layer 44. That is, the first conductor layer 44 is electrically connected to the first doped pillar 22a, the second doped pillar 22b, and the first doped region 16 via the contact windows 44a, 44b, and 44c. The second conductor layer 34 is electrically connected to the second doped region 18. The materials of the first conductor layer 44, the second conductor layer 34, and the contact windows 44a, 44b, and 44c may include Ti, Al, TiN, Ni, Au, or a combination thereof. The contact windows 44a, 44b, and 44c are also referred to as source ohmic contact windows. The first conductor layer 44 is also referred to as a source electrode. The second conductor layer 34 is also referred to as a drain electrode. The first conductor layer 44, the second conductor layer 34, and the contact windows 44a, 44b, and 44c may be simultaneously formed via a deposition process or may be respectively formed.

Referring to FIG. 1F, in the disclosure, the semiconductor device SD1 may include the units U1. Two adjacent units U1 are separated by the first isolation structure 24a and the second isolation structure 24b. The first conductor layer 44 is electrically connected to the first doped regions 16, the first doped pillars 22a, and the second doped pillars 22b of the units U1. The second conductor layer 34 is electrically connected to the second doped regions 18 of the units U1.

Referring to FIG. 1F, in the disclosure, the semiconductor device SD1 includes a metal-oxide semi-field effect transistor with a super junction configuration. The metal-oxide semi-field effect transistor with the super junction configuration has the first doped pillar 22a and the second doped pillar 22b. The metal-oxide semi-field effect transistor with the super junction configuration may establish conduction current along the same path as a traditional high-power metal-oxide semiconductor field-effect transistor (MOSFET) when operating in the forward direction. However, under a reverse bias condition, the first doped pillar 22a and the second doped pillar 22b introduced in the drift region 12 may allow a depletion region to expand, and the depletion region may extend outward until the entire drift region 12 is filled. Such an expansion enlarges the depletion region, so that an electric field distribution within a device is maximized, so the breakdown voltage can be increased. In other words, for the equivalent breakdown voltage, the thickness of the drift region may be reduced, thereby reducing the on-resistance. As the voltage increases, the on-resistance may linearly increase. Compared with the traditional vertical high-power MOSFET, the configuration of the metal-oxide semi-field effect transistor with the super junction configuration of the embodiment of the disclosure can significantly reduce the on-resistance and the power consumption. In some embodiments, an on-resistance R_{ds(on)} may be reduced by 50%. A total gate charge Q_{g} may be reduced by 50%. A reverse recovery time Tᵣᵣ may be reduced by 46%.

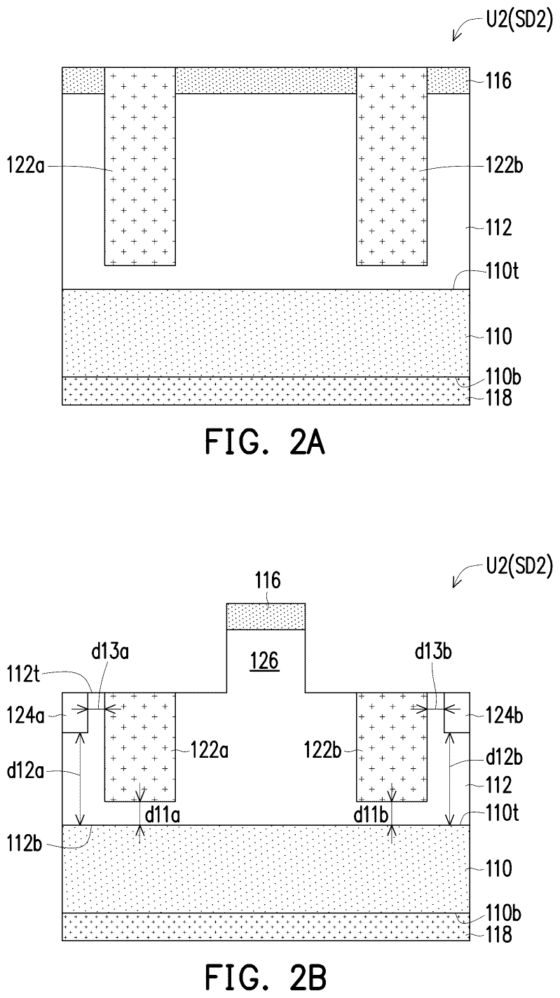

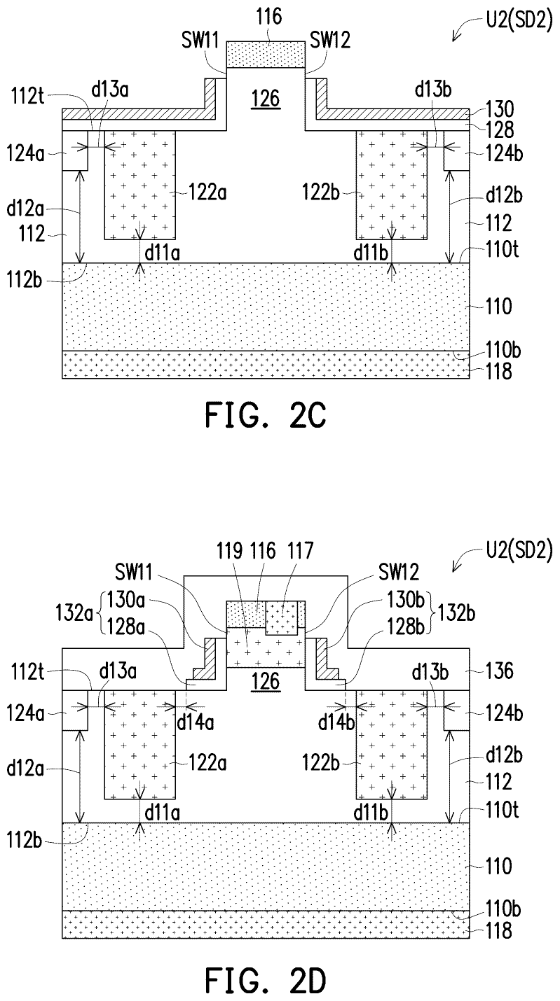

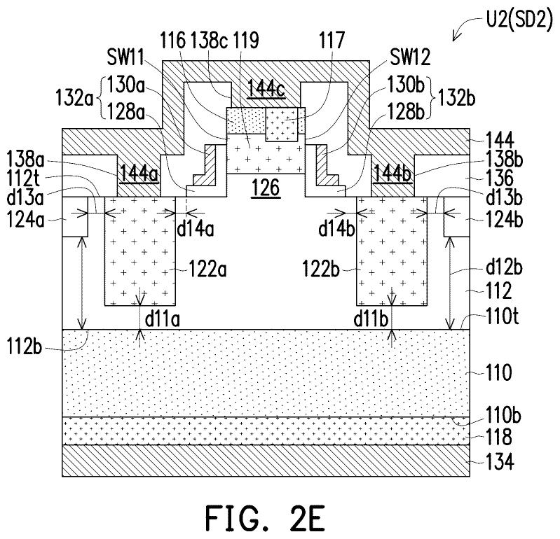

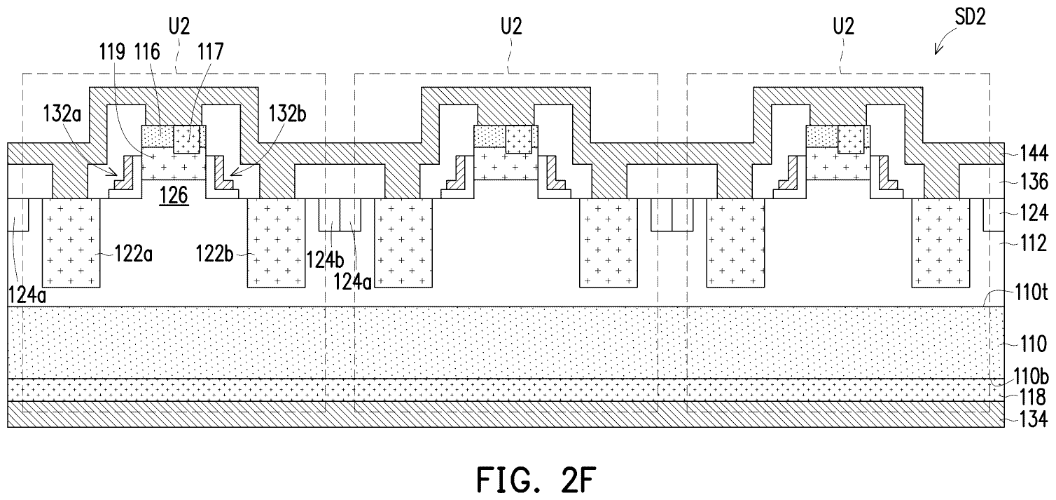

FIG. 2A to FIG. 2F are schematic cross-sectional views of a method of fabricating a semiconductor device according to another embodiment of the disclosure. A semiconductor device SD2 of the embodiment includes multiple units U2. For the sake of simplicity, a single unit U2 is illustrated in FIG. 2A to FIG. 2E. Multiple units U2 are illustrated in FIG. 2F. The semiconductor device SD2 of the embodiment may be an IGBT.

Referring to FIG. 2A, the method of fabricating the semiconductor device SD2 includes forming a drift layer 112 on a first surface 110t of a substrate 110. Next, a first doped region 116 is formed in the drift layer 112, and a second doped region 118 is formed in the substrate 110. The substrate 110, the drift layer 112, and the first doped region 116 have a first conductivity type, such as n type. The substrate 110 is, for example, a semiconductor compound with a first conductivity type. The substrate 110 is, for example, an n-type heavily doped Ga₂O₃ (n+Ga₂O₃) substrate or an n-type heavily doped GaN (n+GaN) substrate. The thickness of the substrate 110 is, for example, 250 μm to 650 μm. The drift layer 112 may be a semiconductor compound with a first conductivity type, such as n-type lightly doped Ga₂O₃ or n-type lightly doped GaN. The first doped region 116 is, for example, n-type heavily doped Ga₂O₃ (n++Ga₂O₃) or n-type heavily doped GaN (n++GaN). The second doped region 118 may be a semiconductor compound with a second conductivity type, such as NiO, Cu₂O, In₂O₃, ZnO, IGZO, other oxide semiconductors, or p-type heavily doped GaN. The depths of the first doped region 116 and the second doped region 118 are, for example, 0.1 μm to 0.5 μm. In the disclosure, the substrate 110 has a first conductivity type, which may cause the electric field of the semiconductor device SD2 to quickly drop to zero when turned off, so the substrate 110 may also be referred to as an electric field stop layer. The first doped region 116 may also be referred to as a p++ emitter region. The second doped region 118 may also be referred to as a p++ collector region.

Afterwards, referring to FIG. 2A, a first doped pillar 122a and a second doped pillar 122b are formed in the drift layer 112. The first doped pillar 122a and the second doped pillar 122b have a second conductivity type, such as p type. The materials of the first doped pillar 122a and the second doped pillar 122b are as the materials of the first doped pillar 22a and the second doped pillar 22b described above, which will not be repeated here.

Referring to FIG. 2B, a photolithography and etching process is performed to pattern a part of the drift layer 112 with the first doped region 116, thereby forming a fin 126. The fin 126 protrudes from a first surface 112t of the remaining drift layer 112 and is located between the first doped pillar 122a and the second doped pillar 122b. Then, a first isolation structure 124a and a second isolation structure 124b are formed in the drift layer 112. The first isolation structure 124a and the second isolation structure 124b may be formed by adopting the same method as the first isolation structure 24a and the second isolation structure 24b.

The first isolation structure 124a, the second isolation structure 124b, the first doped pillar 122a, and the second doped pillar 122b all extend from the first surface 112t of the drift layer 112 toward a second surface 112b. The first doped pillar 122a is spaced from the first surface 112t of the drift layer 112 by a non-zero distance d11a in the longitudinal direction. The second doped pillar 122b is spaced from the first surface 112t of the drift layer 112 by a non-zero distance d11b in the longitudinal direction. The first isolation structure 124a is spaced from the first surface 112t of the drift layer 112 by a non-zero distance d12a in the longitudinal direction. The second isolation structure 124b is spaced from the first surface 112t of the drift layer 112 by a non-zero distance d12b in the longitudinal direction. In the embodiment, the first doped pillar 122a and the second doped pillar 122b are closer to the first surface 112t of the drift layer 112 than the first isolation structure 124a and the second isolation structure 124b. That is, d11a<d12a and d11b<d12b. The distances d11a and d11b are, for example, 0.1 μm to 5 μm. The first isolation structure 24a is adjacent to the first doped pillar 122a and is spaced therefrom by a non-zero distance d13a in the lateral direction. The second isolation structure 124b is adjacent to the second doped pillar 122b and is spaced therefrom by a non-zero distance d13b in the lateral direction.

Referring to FIG. 2C, a gate dielectric layer 128 and a gate conductor layer 130 are formed. The materials of and a method of forming the gate dielectric layer 128 and the gate conductor layer 130 may be the same as the gate dielectric layer 28 and the gate conductor layer 30 described above, which will not be repeated here.

Referring to FIG. 2D, an etching process, a patterning process, or any other feasible process is performed to remove a part of the gate conductor layer 130 and the gate dielectric layer 128 to form gate conductor layers 130a and 130b and gate dielectric layers 128a and 128b. The gate conductor layer 130a and the gate dielectric layer 128a form a first gate structure 132a. The gate conductor layer 130b and the gate dielectric layer 128b form a second gate structure 132b.

Referring to FIG. 2D, a main region 119 and a third doped region 117 are formed in the fin 126. The main region 119 and the third doped region 117 have a second conductivity type. such as p type. The main region 119 is located in the fin 126 below the first doped region 116 and the third doped region 117, and is between the first gate structure 132a and the second gate structure 132b. The material of the main region 119 includes NiO, Cu₂O, In₂O₃, ZnO, IGZO, other oxide semiconductors, or p-type doped GaN. The third doped region 117 extends from a top surface 126t of the fin 126 toward the drift layer 112 and is adjacent to the first doped region 116. The material of the third doped region 117 includes NiO, Cu₂O, In₂O₃, ZnO, IGZO, other oxide semiconductors, or p-type heavily doped GaN. The third doped region 117 may also be referred to as a p+ main lead-out region.

The first gate structure 132a is located between the first doped region 116 and the first doped pillar 122a, is on a lower part of a first side wall SW11 of the fin 126, and extends to the first surface 112t of the drift layer 112. The second gate structure 132b is located between the first doped region 116 and the second doped pillar 122b, is on a lower part of a second side wall SW12 of the fin 126, and extends to the first surface 112t of the drift layer 112.

The gate dielectric layer 128a of the first gate structure 132a and the gate dielectric layer 128b of the second gate structure 132b cover a lower side wall of the main region 119. The gate dielectric layer 128a of the first gate structure 132a may be spaced from the first doped pillar 122a by a non-zero distance d14a. The gate dielectric layer 128a of the first gate structure 132a may be spaced from the first doped pillar 122a by a zero distance (not shown). The gate dielectric layer 128a of the first gate structure 132a may partially cover a top surface (not shown) of the first doped pillar 122a. Likewise, the gate dielectric layer 128b of the second gate structure 132b may be spaced from the second doped pillar 122b by a zero distance (not shown). The gate dielectric layer 128b of the second gate structure 132b may partially cover a top surface (not shown) of the second doped pillar 122b.

Continuing to refer to FIG. 2D, a passivation layer 136 is then formed on the drift layer 112 and the fin 126. The material of the passivation layer 136 may be the same as the material of the passivation layer 36.

Referring to FIG. 2E, a photolithography and etching process is then performed to form contact holes 138a, 138b, and 138c in the passivation layer 136 to expose the first doped pillar 122a, the second doped pillar 122b, the first doped region 116, and the third doped region 117. Afterwards, a first conductor layer 144, a second conductor layer 134, and contact windows 144a, 144b, and 144c are formed. The materials of and a method of forming the first conductor layer 144, the second conductor layer 134, and the contact windows 144a, 144b, and 144c may be the same as the materials of and the method of forming the first conductor layer 44, the second conductor layer 34, and the contact windows 44a, 44b, and 44c.

The contact window 144a electrically connects the first doped pillar 122a and the first conductor layer 144. The contact window 144b electrically connects the second doped pillar 122b and the first conductor layer 144. The contact window 144c electrically connects the first doped region 16 and the third doped region 117 to the first conductor layer 144. The first conductor layer 144 is electrically connected to the first doped pillar 122a, the second doped pillar 122b, the first doped region 116, and the third doped region 117 via the contact windows 144a, 144b, and 144c. The second conductor layer 134 is electrically connected to the second doped region 118. The first conductor layer 144 may be used as an emitter electrode. The second conductor layer 134 may be used as a collector electrode. The gate conductor layers 130a and 130b of the first gate structure 132a and the second gate structure 132a may be used as gates.

The fin 126, the drift layer 12, the substrate 10, the first gate structure 132a, the second gate structure 132a, the first doped region 116, the second doped region 118, the third doped region 117, the main region 119, the first doped pillar 122a, and the second doped pillar 122b of the embodiment of the disclosure form the unit U2 of the semiconductor device SD2.

Referring to FIG. 2F, in the disclosure, the semiconductor device SD2 may include the units U2. Two adjacent units U2 are separated by the first isolation structure 124a and the second isolation structure 124b. The first conductor layer 144 is electrically connected to the first doped regions 116, the third doped regions 117, the main regions 119, the first doped pillars 122a, and the second doped pillars 122b of the units U2. The second conductor layer 134 is electrically connected to the second doped regions 118 of the units U2.

When the semiconductor device SD2 is turned off, the channel is quickly cut off, and there is no more carrier current, but there are still fewer carrier holes injected at an collector end, so the current of the entire semiconductor device SD2 needs to be slowly turned off, thereby affecting the turn-off time and the working frequency of the semiconductor device SD2. Therefore, the drift layer 112 is added between the second doped region 118 (a P+ injection layer) and the first doped region 116. The function of the drift layer 112 is to enable the holes injected from the collector end to be quickly combined in this layer (the drift layer 112) when the semiconductor device SD2 is turned off to increase the turn-off frequency. However, if high power needs to be simultaneously achieved, a collector-emitter saturation voltage (Vce(sat)) needs to be reduced, that is, an on-resistance (Ron) needs to be reduced. Therefore, it is necessary to reduce the thickness of the drift layer 112, but the thickness of the drift layer 112 is also limited by a cut-off electric field, because if the drift layer 112 is too thin, the channel may be easily passed through. If the thickness of the drift layer needs to be reduced, the cut-off electric field must drop in advance before reaching the channel. Therefore, in the disclosure, the substrate 110 is introduced between the second doped region 118 (the P+ injection layer) and the drift layer 112 as a field stop (FS) layer. When the semiconductor device SD2 is turned off, the electric field within the substrate 110 quickly drops to 0, implementing termination. Therefore, in the disclosure, the thickness of the drift layer 112 may be further reduced to reduce the on-resistance (Ron) and the collector-emitter saturation voltage (Vce(sat)).

In summary, the metal-oxide semi-field effect transistor with the super junction configuration according to the embodiment of the disclosure has the doped pillars, which can expand the depletion region, so that the electric field distribution within the device is maximized. Therefore, the breakdown voltage can be increased, and the on-resistance and the power consumption can be significantly reduced. The IGBT according to the embodiment of the disclosure has the FS layer, which enables the electric field within the FS layer to quickly drop to 0 when the device is turned off. Therefore, in the disclosure, the thickness of the drift layer may be further reduced to reduce the on-resistance (Ron) and the collector-emitter saturation voltage (Vce(sat)).

What is claimed is:

1. A semiconductor device, comprising a plurality of units, wherein each of the units comprises:
a substrate;
a drift layer, located on a first surface of the substrate;
a fin, located on a first surface of the drift layer;
a first doped region, located in the fin and extending from a top surface of the fin toward the drift layer;
a second doped region, located in the substrate and extending from a second surface of the substrate toward the first surface of the substrate;
a first doped pillar, located in the drift layer and extending from the first surface of the drift layer toward a second surface of the drift layer; and
a first gate structure, between the first doped region and the first doped pillar, on a first side wall of the fin, and extending to the first surface of the drift layer.

2. The semiconductor device according to claim 1, further comprising:
a second doped pillar, located in the drift layer and extending from the first surface of the drift layer toward the second surface of the drift layer; and
a second gate structure, between the first doped region and the second doped pillar, on a second side wall of the fin, and extending to the first surface of the drift layer.

3. The semiconductor device according to claim 2, wherein cross sections of the first gate structure and the second gate structure are respectively L-shaped.

4. The semiconductor device according to claim 2, further comprising:
a first isolation structure, located in the drift layer and spaced from the first doped pillar by a non-zero distance in a lateral direction; and
a second isolation structure, located in the drift layer and spaced from the second doped pillar by a non-zero distance in the lateral direction.

5. The semiconductor device according to claim 2, wherein the first doped region and the second doped region have a first conductivity type, and the first doped pillar and the second doped pillar have a second conductivity type.

6. The semiconductor device according to claim 5, wherein:
the first doped region comprises Si or Sn dopants; and
the first doped pillar and the second doped pillar comprise NiO, Cu₂O, In₂O₃, ZnO, IGZO, other oxide semiconductors, or p-type GaN.

7. The semiconductor device according to claim 5, further comprising:
a first conductor layer, electrically connected to the first doped regions, the first doped pillars, and the second doped pillars of the units; and
a second conductor layer, electrically connected to the second doped regions of the units.

8. The semiconductor device according to claim 2, further comprising:
a third doped region, located in the fin and adjacent to the first doped region; and
a main region, located in the fin below the first doped region and the third doped region, and between the first gate structure and the second gate structure,
wherein the first gate structure is located between the second doped region and the first doped pillar, and the second gate structure is located between the third doped region and the second doped pillar.

9. The semiconductor device according to claim 8, wherein the first doped region has a first conductivity type, and the second doped region, the first doped pillar, the second doped pillar, and the third doped region have a second conductivity type.

10. The semiconductor device according to claim 9, wherein:
the first doped region comprises Si or Sn dopants;
the second doped region comprises NiO, Cu₂O, In₂O₃, ZnO, IGZO, other oxide semiconductors, or p-type heavily doped GaN;
materials of the first doped pillar and the second doped pillar comprise NiO, Cu₂O, In₂O₃, ZnO, IGZO, other oxide semiconductors, or p-type doped GaN; and
a material of the third doped region comprises NiO, Cu₂O, In₂O₃, ZnO, IGZO, other oxide semiconductors, or p-type heavily doped GaN.

11. The semiconductor device according to claim 9, further comprising:
a first conductor layer, electrically connected to the first doped regions, the first doped pillars, the second doped pillars, and the third doped regions of the units; and
a second conductor layer, electrically connected to the second doped regions of the units,
wherein the first conductor layer is an emitter electrode, and the second conductor layer is a collector electrode.

12. The semiconductor device according to claim 1, wherein the substrate comprises an n-type heavily doped Ga₂O₃ substrate or an n-type heavily doped GaN substrate, and a material of the drift layer comprises n-type lightly doped Ga₂O₃ or n-type lightly doped GaN.

13. A method of fabricating a semiconductor device, comprising:
providing a substrate;
forming a plurality of units, wherein forming each of the units comprises:
forming a drift layer on a first surface of the substrate;
forming a first doped region in the drift layer;
patterning a part of the drift layer with the first doped region to form a fin;
forming a second doped region on a second surface of the substrate;
forming a first doped pillar extending from a first surface of the drift layer toward a second surface of the drift layer in the drift layer; and
forming a first gate structure extending to the first surface of the drift layer between the first doped region and the first doped pillar and on a first side wall of the fin.

14. The method of fabricating the semiconductor device according to claim 13, further comprising:
forming a second doped pillar extending from the first surface of the drift layer toward the second surface of the drift layer in the drift layer; and
forming a second gate structure extending to the first surface of the drift layer between the first doped region and the second doped pillar and on a second side wall of the fin.

15. The method of fabricating the semiconductor device according to claim 14, wherein forming the first gate structure and the second gate structure comprises:
forming a gate dielectric layer and a gate conductor layer on the first surface of the drift layer and the first side wall, a top surface, and the second side wall of the fin;
forming a mask layer to cover the gate conductor layer;
removing a part of the mask layer to expose a first portion of the gate conductor layer, wherein the first portion of the gate conductor layer covers the top surface, a part of the first side wall, and a part of the second side wall of the fin and;
using the remaining mask layer as a mask, and etching to remove the first portion of the gate conductor layer and the covered gate dielectric layer to expose the first doped region, a part of the first side wall, and a part of the second side wall; and
removing the remaining mask layer.

16. The method of fabricating the semiconductor device according to claim 14, wherein the first doped region and the second doped region have a first conductivity type, and the first doped pillar and the second doped pillar have a second conductivity type.

17. The method of fabricating the semiconductor device according to claim 16, further comprising:
forming a first conductor layer electrically connected to the first doped regions, the first doped pillars, and the second doped pillars of the units; and
forming a second conductor layer electrically connected to the second doped regions of the units.

18. The method of fabricating the semiconductor device according to claim 14, further comprising:
forming a third doped region in the fin, wherein the third doped region is adjacent to the first doped region; and
forming a main region in the fin below the first doped region and the third doped region, wherein the main region is between the first gate structure and the second gate structure,
wherein the first gate structure is located between the second doped region and the first doped pillar, and the second gate structure is located between the third doped region and the second doped pillar.

19. The method of fabricating the semiconductor device according to claim 18, wherein the first doped region has a first conductivity type, and the second doped region, the first doped pillar, the second doped pillar, and the third doped region have a second conductivity type.

20. The method of fabricating the semiconductor device according to claim 19, further comprising:
forming a first conductor layer electrically connected to the first doped regions, the first doped pillars, the second doped pillars, and the third doped regions of the units; and
forming a second conductor layer electrically connected to the second doped regions of the units,
wherein the first conductor layer is an emitter electrode, and the second conductor layer is a collector electrode.
